(19) United States
(12) Patent Application Publication
(10) Pub. No.: US 2010/0081572 A1
(43) Pub. Date: Apr. 1, 2010

(54) FLUIDLESSLY COOLED SUPERCONDUCTING TRANSMISSION LINES AND REMOTE NUCLEAR POWERSYSTEMS THEREFROM

(76) Inventor: NEIL R. JETTER, PALM BEACH GARDENS, FL (US)

Correspondence Address: NEIL R. JETTER, 8705 NASHUA DRIVE, PALM BEACH GARDENS, FL, 33418, US

(21) Appl. No.: 12/436,021

(22) Filed: May 5, 2009

Related U.S. Application Data
(60) Provisional application No. 61/050,519, filed on May 5, 2008.

(51) Int. Cl. H01L 39/02; H01B 12/00; H01B 7/30

(52) U.S. Cl. 505/160; 505/166; 505/230; 307/147

(57) ABSTRACT

A superconducting transmission line includes a superconducting article including at least one HTS wire, a cooling system including at least in part one or more thermoelectric or thermionic coolers thermally coupled to the HTS wire. The thermoelectric coolers are powered by electricity flowing along the HTS wire. A system for generating and transporting nuclear power includes a nuclear power plant including a turbine for generating electricity, and a superconducting transmission line according to an embodiment of the invention.

### CROSS REFERENCE TO RELATED APPLICATIONS

This application claims the benefit of Provisional Application Ser. No. 61/050,519 entitled “REMOTELY LOCATED NUCLEAR POWER GENERATOR INCLUDING SUPERCONDUCTING TRANSMISSION LINES”, filed May 5, 2008, which is herein incorporated by reference in its entirety.

### FIELD OF THE INVENTION

Embodiments of the present invention relate to superconductors, and transmission of electricity therethrough, such as electricity generated from a nuclear power plant.

### BACKGROUND

Nuclear power is a type of nuclear technology comprising the controlled use of nuclear reactions, usually nuclear fission, to release energy for performing work including propulsion, heat, and/or the generation of electricity. Nuclear energy is produced by a controlled nuclear chain reaction which creates heat which is generally used to boil water, produce steam, and drive a steam turbine. The turbine can be used for mechanical work and also to generate electricity.

In nuclear fission, as known in the art, when a relatively large fissile atomic nucleus is struck by a neutron it forms two or more smaller nuclei as fission products, releasing energy and neutrons. The chain reaction is controlled through the use of materials that absorb and moderate neutrons. In uranium-fueled reactors, neutrons must be moderated (slowed down) because slow neutrons are more likely to cause fission when colliding with a uranium-235 nucleus. Light water reactors use ordinary water to moderate and cool the reactors. When at operating temperatures if the temperature of the water increases, its density drops, and fewer neutrons passing through it are slowed enough to trigger further reactions. That negative feedback stabilizes the reaction rate.

Uranium is a fairly common element in the Earth's crust. Uranium is approximately as common as tin or germanium in Earth's crust, and is about 35 times as common as silver. Uranium is a constituent of most rocks, dirt, and of the oceans. Another alternative would be to use uranium-233 bred from thorium as fission fuel in the thorium fuel cycle. Thorium is about 3.5 times as common as uranium in the Earth's crust, and has different geographic characteristics. This would extend the total practical fissionable resource base by over 400%.

Nuclear fusion commonly proposes the use of deuterium, an isotope of hydrogen, as fuel and in many current designs also lithium. Assuming a fusion energy output equal to the current global output and that this does not increase in the future, then the known current lithium reserves would last 3,000 years, lithium from sea water would last 60 million years, and a more complicated fusion process using only deuterium from sea water would have fuel for 150 billion years.

Like conventional power plants, nuclear power plants generate large quantities of waste heat which is expelled in the condenser, following the turbine. The safe storage and disposal of nuclear waste is a significant challenge. The most important waste stream from nuclear power plants is spent fuel. A large nuclear reactor can produces 3 cubic meters (25-30 tons) of spent fuel each year. It is primarily composed of unconverted uranium as well as significant quantities of transuranic actinides (plutonium and curium, mostly). High level radioactive waste

Spent fuel is highly radioactive and needs to be handled with great care. Spent fuel rods are stored in shielded basins of water (spent fuel pools), usually located on-site. The water provides both cooling for the still-decaying fission products, and shielding from the continuing radioactivity. After a few decades some on-site storage involves moving the now cooler, less radioactive fuel to a dry-storage facility or dry cask storage, where the fuel is stored in steel and concrete containers until its radioactivity decreases naturally (“decays”) to levels safe enough for other processing. This interim stage spans years or decades, depending on the type of fuel.

Proponents of nuclear energy argue that nuclear power is a sustainable energy source that reduces carbon emissions and increases energy security by decreasing dependence on foreign oil. Proponents also claim that the risks of storing waste are small and can be further reduced by the technology in the new reactors and the operational safety record is already good when compared to the other major kinds of power plants. However, critics claim that nuclear power is a potentially dangerous energy source. Critics also point to the problem of storing radioactive waste, the potential for possibly severe radioactive contamination of the area surrounding the nuclear plant by accident or sabotage (e.g., terrorism). The two most well-known nuclear accidents are the Three Mile Island accident and the Chernobyl disaster.

The Chernobyl disaster in 1986 at the Chernobyl Nuclear Power Plant in the Ukrainian Soviet Socialist Republic (now Ukraine) was the worst nuclear accident. The power excursion and resulting steam explosion and fire spread radioactive contamination across a significant portion of Europe. The 1979 accident at Three Mile Island Unit 2 was the worst civilian nuclear accident outside the Soviet Union (INES score of 5). The reactor experienced a partial core meltdown. However, according to the NRC, the reactor vessel and containment building were not breached and little radiation was released to the environment, with no significant impact on health or the environment.

For the future, fusion reactors, which may be viable in the future, have no risk of explosive radiation-releasing accidents, and even smaller risks than the already extremely small risks associated with nuclear fission. Whilst fusion power reactors will produce a very small amount of reasonably short lived, intermediate-level radioactive waste at decommissioning time, as a result of neutron activation of the reactor vessel, they will not produce any high-level, long-lived materials comparable to those produced in a fission reactor.

The possible adverse health effect on population near nuclear plants is a major reason nuclear power has not become commonplace in the world. Some areas of Britain near industrial facilities, particularly near Sellafield, have displayed elevated childhood leukemia levels, in which children living locally are 10 times more likely to contract the cancer. Likewise, small studies have found an increased incidence of childhood leukemia near some nuclear power plants has been found in Germany and France.

Nuclear power plants may have vulnerability to attack. However, nuclear power plants are generally (although not always) considered “hard” targets. In the U.S., nuclear plants are surrounded by a double row of tall fences which are electronically monitored. The plant grounds are patrolled by a sizeable force of armed guards. Attack from the air is a more problematic concern. The most important barrier against the release of radioactivity in the event of an aircraft strike is the containment building and its missile shield. In addition, supporters point to large studies carried out by the US Electric Power Research Institute that tested the robustness of both reactor and waste fuel storage, and found that they should be able to sustain a terrorist attack comparable to the Sep. 11, 2001 terrorist attacks in the USA. Spent fuel is usually housed inside the plant's “protected zone” or a spent nuclear fuel shipping cask; stealing it for use in a “dirty bomb” is extremely difficult. Exposure to the intense radiation would almost certainly quickly incapacitate or kill any terrorists who attempt to do so.

In conclusion, although nuclear power is capable of supplying the majority of world power likely for at least the next 100 years, the risk of accident or terrorism at a nuclear power plant as well as the disposal of nuclear waste currently limits the use of nuclear power. Since conventional copper wire power distribution systems are only capable of distributing power from power plants on the order of several miles (even using high voltage transmission) due to resistive loss, power plants including nuclear reactors and their waste generated have always been located near the population center served by the plant. Accordingly, a significant obstacle to nuclear energy has generally been the presence of the nuclear reactor close to the community in which the power is needed.

### BRIEF DESCRIPTION OF THE DRAWINGS

FIG. 1 is a schematic diagram of power transmission system comprising a superconducting article and a plurality of thermoelectric or thermionic coolers thermally coupled to the superconducting article for providing cryogenic cooling for the superconducting article.

FIG. 2 shows a depiction of a system comprising a nuclear power plant including a turbine for generating electricity, wherein the plant is positioned in a location that is generally at least 10 miles and is typically at least 50 miles from any population center, and includes the power transmission system shown in FIG. 1.

### DETAILED DESCRIPTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

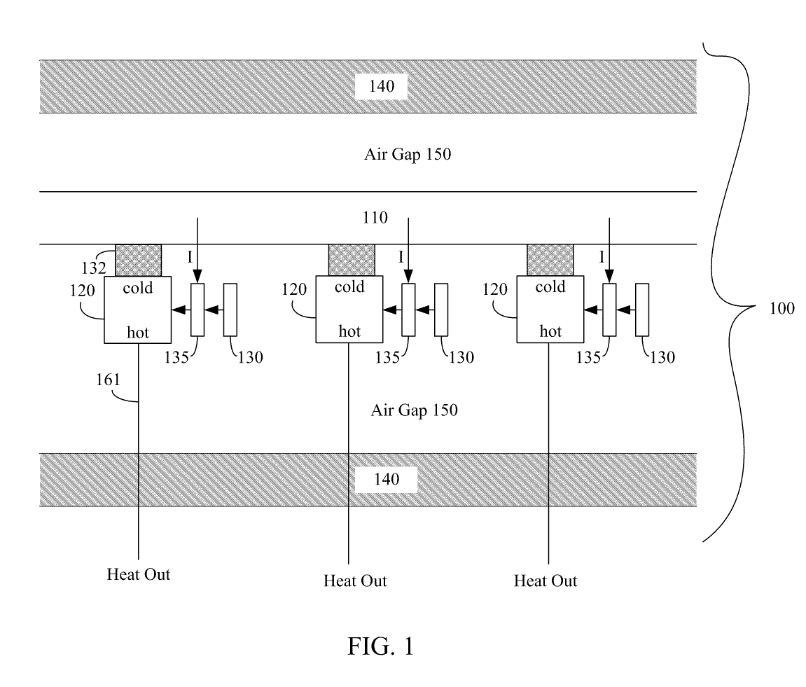

One embodiment of the present invention comprises a power transmission system comprising a superconducting article and at least one, and generally a plurality of thermoelectric coolers or thermionic coolers for providing cryogenic cooling coupled to the superconducting article, such as superconducting wire. Referring to FIG. 1, a schematic diagram of power transmission system 100 comprising a superconducting article 110 and a plurality of thermoelectric or thermionic coolers 120 thermally coupled by thermally conductive coupling material 132 to the superconducting article 110 for providing cryogenic cooling for the superconducting article 110, is shown. Superconducting article 110 is typically a superconducting wire comprising article, such as a multi-wire HTS transmission cable.

The HTS transmission line can comprise a plurality of individual HTS cables running in parallel, containing ribbon-shaped HTS wires. As known in the art, such HTS wires can conduct 150 times the electricity of similar sized copper wires, using much lower voltage than copper. Embodiments of the present invention can utilize other HTS wire embodiments.

System 100 includes temperature sensors 130 proximate to the superconducting article that outputs a signal based on the measured temperature that actuates a switch 135 that directs current (I) from the superconducting article 110 to the thermoelectric or thermionic coolers 120 when cooling is needed. Conveniently, the electrical energy to run the thermoelectric or thermionic coolers 120 can be supplied by electricity transmitted along superconducting article 110 (e.g., HTS wires).

A thermally insulating isolation structure 140 thermally isolates system 100 from the ambient. An air gap 150 is shown between superconducting article 110. As described below, thermally insulating isolation structure 140 can comprise ice, with a porous thermal insulator such as snow thereon in one embodiment. A thermally conductive conduit 161 is coupled to the hot side of thermoelectric or thermionic cooler 120 for conducting heat away from system 100 by transmitting the heat outside of thermally insulating isolation structure 140 as shown in FIG. 1.

The thermoelectric or thermionic cooler 120 thus provides cooling without a working fluid to ensure the superconducting article is held at a temperature low enough so that superconducting properties are provided by the superconducting article 110. Temperature sensors 130 coupled with switches along the length of the superconducting article 110 can be used to independently trigger operation of the thermoelectric or thermionic coolers 120 by closing switch 135 to flow current I to thermoelectric or thermionic coolers 120 generally only when required to maintain the temperature proximate to the superconducting article below a predetermined temperature. The current to power the thermoelectric or thermionic cooler can generally by obtained from current by conducted by the superconducting article, this removing the need for conventional liquid nitrogen (LN2) cooling which requires continuous generation of LN2.

Thermoelectric coolers are well known and even sold commercially. Although not widely recognized, thermoelectric coolers can provide cooling to obtain cryogenic temperatures from conventional ambient conditions. For example, U.S. Pat. No. 6,505,468 ('468 application) discloses a cascade thermoelectric cooler comprising a plurality of thermoelectric coolers cascaded in series to cool to cryogenic temperatures of 30 to 120 K. The superconductor aspect disclosed in '468 is regarding the cooling of superconducting coils, specifically for electric motors or generators. In one embodiment '468 discloses combination of a thermoelectric cooler with liquid nitrogen cooling. For example, FIG. 6 is a schematic of an electric apparatus utilizing superconducting coils being cooled by a thermoelectric cascade cooler coupled between room temperature and cryogenic temperatures of the superconducting coils. This embodiment requires no liquid nitrogen. '468 application is hereby incorporated by reference into the present application.

A thermionic device is a device for converting heat into electricity through the use of thermionic emission and uses no working fluid, just simply electric charges. An elementary thermionic generator, or thermionic converter, consists of a hot metal surface (emitter) separated from a cooler electrode (collector) by an insulator seal. By cascading a plurality of thermionic coolers as disclosed in the '468 application, such a cooler can provide cooling sufficient to obtain cryogenic temperatures from conventional ambient conditions.

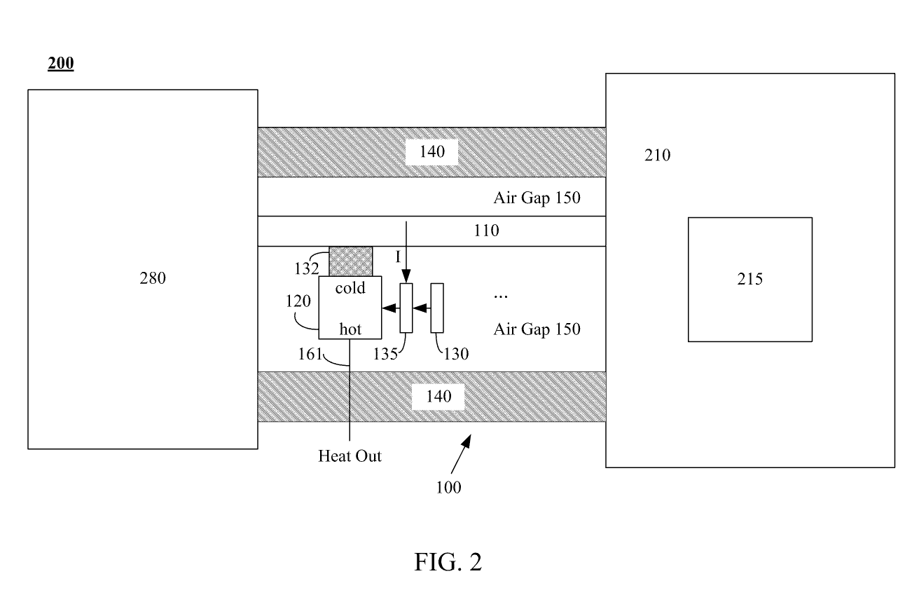

Another embodiment of the present invention provides a nuclear plant and a power transmission system described above that can largely overcome the geographic proximity problem to allow nuclear power to begin supplying a significant portion of world's power needs, if not the majority of its needs. FIG. 2 shows a depiction of a power generation and power distribution system 200 according to an embodiment of the present invention. System 200 comprises a nuclear power plant 210 including a turbine 215 for generating electricity, wherein the plant is positioned in a location that is generally at least 10 miles and is typically at least 50 miles from any population center, and the power transmission system 100 shown in FIG. 1.

Superconducting article 110 of typically comprises HTS wire is coupled to receive and transport the electricity generated at the plant at least a portion of the distance between the plant location and a user of the electricity generated or system for generating another energy form generated from the electricity 280. In one embodiment, the location comprises Antarctica or the arctic, or a location near the arctic circle, so that thermally insulating isolation structure 140 comprises ice. For example, in the U.S., many locations in the state of Alaska may generally be used.

The nuclear plant can generally be any nuclear plant. In one embodiment, the nuclear plant includes superconducting transmission lines to provide electrical power at least 10 miles from the plant. The power can then be used by a system for generating another energy 280 to generate a fuel, such as hydrogen (e.g. from water, such as by electrolysis) which can be piped over long distances analogous to how natural gas and propane are transported currently.

Recent superconductor technology advances have provided relatively low cost, high quality superconducting wire based electrical transmission lines with the proven capability transmit electricity almost one mile, with the capability to scale to span tens or hundreds of miles. For example, it was recently reported that a 2,000-foot (about 4/10 of a mile) long superconducting cable, made with wire produced by American Superconductor Corporation Devens, MA, was installed in Holbrook, N.Y. which is on Long Island. The installation was not a test, rather, actually a live part of their power grid, and actually one of the most critical parts of their power grid. The Long Island Power Authority has already begun utilizing the 138 kvolt system, which is able to handle 574 megawatts of power, according to American Superconductor. It was asserted that “The entire power output of a traditional coal-fired or gas-fired or nuclear power plant could flow through this one cable.”

By positioning nuclear power plants in desolate locations uninhabited by humans, such as in artic and Antarctic regions, deserts, or even portions of certain oceans, the electricity generated by the power plant can be provided to distant locations for consumption by superconducting wires which can supply power long distances with relatively modest resistive losses. Locating nuclear plants in desolate locations provides the ability to fortify the plant to prevent terrorist incursion and also provide a convenient location for storing spent fuel on site.

As known in the art of superconductors, superconductors require cooling to near liquid nitrogen temperatures to provide their superconducting properties. High-temperature superconductors (abbreviated high Tc) are a family of superconducting materials containing copper-oxide planes as a common structural feature. This feature allows some materials to support superconductivity at temperatures above the boiling point of liquid nitrogen (77 K or −196° C.). Indeed, they offer the highest transition temperatures of all known superconductors.

The ability to use relatively inexpensive and easily handled liquid nitrogen as a coolant has increased the range of practical applications of superconductivity. Liquid nitrogen is a compact and readily transported source of nitrogen gas without pressurization. Further, its ability to maintain temperatures far below the freezing point of water makes it extremely useful in a wide range of applications, including superconductors.

One significant advantage of locating the nuclear plant in an arctic or Antarctic location, or a near arctic location such as some locations in Alaska or Canada, is that the very low ambient temperature reduces the challenge of maintaining the required low temperature (e.g., ≦100 to 120 K for currently available HTS). Average January temperatures in the arctic generally range from about −40 to 0° C., and winter temperatures can drop below −50° C. over large parts of the Arctic. Average July temperatures in the arctic range from about −10 to +10° C. For example, assuming a nominal arctic or Antarctic temperature of −10° C. (263 K) the cooling requirement (Δ K=Δ ° C.) for currently available HTS would be 143 to 163 K. In contrast, a typical temperate location may be around 27° C. (300 K), making the cooling requirement (Δ K) for currently available HTS be 180 to 200 K. In one embodiment, superconducting wires are located above the ground analogous to conventional above the grounds power distribution systems. The superconducting wires may also be positioned under the ice, which may assist in maintaining a low temperature particularly during the summer months.

As disclosed above, the electricity generated at the plant and carried by the superconducting transmission lines can be converted to another energy form before reaching the user. For example, in one embodiment, electricity is used to generate hydrogen gas (H₂) from water using electricity (by electrolysis). Conventional electrolysis is a low temperature process.

In contrast with low-temperature electrolysis, high-temperature electrolysis (HTE) electrolysis of water converts more of the initial heat energy into chemical energy (hydrogen), potentially doubling efficiency, to about 50%. Because some of the energy in HTE is supplied in the form of heat, less of the energy must be converted twice (from heat to electricity, and then to chemical form), and so less energy is lost. HTE has been demonstrated in laboratories, but not yet at a commercial scale. Once generated, hydrogen does not require cooling. The hydrogen could then by piped analogous to how natural gas or propane and other parts of the world today.

In one particular embodiment, a plurality of fuel generation plant can surround the nuclear plant, such as at a distance of 10 to 50 miles, and located along a circle (or more generally an ellipse) at zero degrees, 90 degrees, 180 degrees and 270 degree position relative to the nuclear plant. Defense establishments may be co-located with the fuel generation plants to secure the fuel generation plants as well as the nuclear plant at the center of the arrangement from threats including terrorist attacks.

Embodiments of the invention can be embodied in other forms without departing from the spirit or essential attributes thereof and, accordingly, reference should be had to the following claims rather than the foregoing specification as indicating the scope of the invention.

In the preceding description, certain details are set forth in conjunction with the described embodiment of the present invention to provide a sufficient understanding of the invention. One skilled in the art will appreciate, however, that the invention may be practiced without these particular details. Furthermore, one skilled in the art will appreciate that the example embodiments described above do not limit the scope of the present invention and will also understand that various modifications, equivalents, and combinations of the disclosed embodiments and components of such embodiments are within the scope of the present invention.

Moreover, embodiments including fewer than all the components of any of the respective described embodiments may also within the scope of the present invention although not expressly described in detail. Finally, the operation of well known components and/or processes has not been shown or described in detail below to avoid unnecessarily obscuring the present invention.

One skilled in the art will understood that even though various embodiments and advantages of the present Invention have been set forth in the foregoing description, the above disclosure is illustrative only, and changes may be made in detail, and yet remain within the broad principles of the invention.

1. A system for generating and transporting nuclear power including superconducting power transmission, comprising:
a nuclear power plant including a turbine for generating electricity,
a superconducting transmission line, comprising:
a superconducting article comprising at least one HTS wire coupled to receive and transport said electricity at least a portion of a distance between said location of said plant and at least one user of said electricity or an energy form generated from said electricity;
a cooling system comprising at least in part one or more thermoelectric or thermionic coolers thermally coupled to said HTS wire, wherein said thermoelectric coolers are powered by electricity flowing along said HTS wire.

2. The system of claim 1, wherein cooling for said HTS transmission line is provided at least in part by thermoelectric or thermionic coolers.

3. The system of claim 1, further comprising a system for receiving said electricity from said transmission lines and converting said electricity to a fuel.

4. The system of claim 3, wherein said fuel is hydrogen, and said HTS transmission line is at least 10 miles in length.

5. The system of claim 1, wherein said location comprises Alaska, the arctic, the Antarctic or Canada.

6. The system of claim 5, wherein said HTS transmission line is located under the ground and is surrounded by ice.

7. The system of claim 1, further comprising a military installation proximate to said plant having armaments for repelling enemy attacks from both air and ground.

8. The system of claim 1, wherein said superconducting transmission line is at least 10 miles long and said location is at least 10 miles from any population center.

9. A superconducting transmission line, comprising:
a superconducting article comprising at least one HTS wire;
a cooling system comprising at least in part one or more thermoelectric or thermionic coolers thermally coupled to said HTS wire, wherein said thermoelectric coolers are powered by electricity flowing along said HTS wire.

10. The superconducting transmission line of claim 9, further comprising at least one temperature sensor proximate to said HTS wire, and a switch, wherein a signal from said temperature sensor is for controlling a flow of current from said HTS wire supplied to said thermoelectric or thermionic coolers.

11. The transmission line of claim 9, wherein said cooling system is configured for achieving a temperature of <120 K proximate to said HTS wire.
